(19) United States
(12) Patent Application Publication
(10) Pub. No.: US 2010/0012926 A1
(43) Pub. Date: Jan. 21, 2010

(54) Organic electroluminescent device

(76) Inventors: Jun-Yeob Lee, Suwon-si (KR); Jang-Hyuk Kwon, Suwon-si (KR); Min-Seung Chun, Suwon-si (KR); Yong-Joong Choi, Suwon-si (KR)

Correspondence Address: ROBERT E. BUSHNELL & LAW FIRM, 2029 K STREET NW, SUITE 600, WASHINGTON, DC, 20006-1004, US

(21) Appl. No.: 11/125,113

(22) Filed: May 10, 2005

(30) Foreign Application Priority Data
Jun. 15, 2004 (KR) 10-2004-0044117

(51) Int. Cl. H01L 51/54; H01J 1/63

(52) U.S. Cl. 257/40; 313/504; 257/E51.026; 257/E51.022

(57) ABSTRACT

An organic EL device is constructed with a first electrode, a light-emitting layer, a second electrode, and an organic layer which includes a biphenylenediamine compound and is interposed between the first electrode and the light-emitting layer. The organic layer formed between the first electrode and the light-emitting layer has both hole transport and hole injection properties. With this structure, the organic EL device has improved lifetime characteristics in spite of absence of a hole injection layer. A buffer layer including an organic compound with p-type semiconductive property may be further formed between the first electrode and the organic layer including the 4,4′-biphenylenediamine compound to facilitate hole injection from the first electrode and transport an injected hole to the light-emitting layer. Therefore, the organic EL device can have a lower driving voltage, thereby improving a device lifetime.

### CLAIM OF PRIORITY

This application claims the priority of Korean Patent Application No. 2004-44117, filed on Jun. 15, 2004, in the Korean Intellectual Property Office, the disclosure of which is incorporated herein in its entirety by reference.

### BACKGROUND OF THE INVENTION

1. Field of the Invention

The present invention relates to an organic electroluminescent device, and more particularly, to an organic electroluminescent device with improved lifetime characteristics.

2. Description of the Related Art

Organic electroluminescent (EL) devices have a basic structure that has a light-emitting layer between a second electrode and a first electrode. To enhance emission efficiency and lifetime characteristics of the organic EL devices with such a basic structure, a hole transport layer is formed between the first electrode and the light-emitting layer, and an electron transport layer is formed between the light-emitting layer and the second electrode.

The hole transport layer is made of an aromatic tertiary amine, for example, TPD (N,N-diphenyl-N,N′-bis(3-methylphenyl)-1,1′-biphenyl-4,4′-diamine) or arylene diamine derivative (Japanese Patent Laid-Open Publication No. Hei. 3-231970, U.S. Pat. No. 5,837,166 entitled Organic Electroluminescence Device and Arylenediamine Derivative to Kawamura, et al. and issued on Nov. 17, 1998 and U.S. Pat. No. 5,061,569 entitled Electroluminescent Device with Organic Electroluminescent Medium to VanSlyke, et al. and issued on Oct. 29, 1991).

In the organic EL devices, a hole injection layer made of copper phthalocyanine or Starburst amine compound is interposed between the first electrode used as an anode and the hole transport layer to satisfy requirements of device characteristics such as driving voltage. At this time, the hole injection layer is formed to a thickness of 100 Å or more.

However, the above-described sequential formation of the hole injection layer and the hole transport layer on the anode lengthens device manufacturing processes.

### SUMMARY OF THE INVENTION

It is therefore an object of the present invention to provide an improved organic EL device.

It is another object of the present invention to provide an organic EL device that is excellent in emission efficiency and lifetime characteristics in spite of absence of a hole injection layer.

According to an aspect of the present invention, an organic EL device may be constructed with a first electrode, a second electrode, a light-emitting layer formed between the first electrode and the second electrode, and an organic layer interposed between the first electrode and the light-emitting layer, the organic layer comprising a compound represented by the following formula 1:

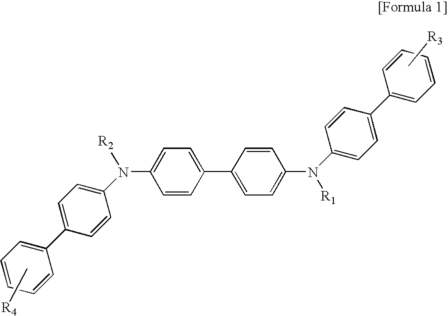

wherein R₁ and R₂ are each independently a substituted or unsubstituted alkyl group of C1-C20 or a substituted or unsubstituted aryl group of C6-C20, R₃ and R₄ are each independently selected from the group consisting of a substituted or unsubstituted alkyl group of C1-C20, a substituted or unsubstituted aryl group of C6-C20, a halogen atom, a nitro group, a cyano group, and an alkoxy group of C1-C20.

The organic layer including the compound of the formula 1 may have both hole transport and hole injection properties. The organic layer may have a thickness of 50 to 2,000 Å.

The organic EL device may further include a buffer layer including an organic compound with p-type semiconductive property between the first electrode and the organic layer.

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIG. 1 illustrates a sectional view of an organic EL device according to an embodiment of the present invention; and

FIG. 2 illustrates a sectional view of an organic EL device according to another embodiment of the present invention.

### DETAILED DESCRIPTION OF THE PREFERRED EMBODIMENTS

Hereinafter, the present invention will be described in more detail.

An organic EL device of the present invention includes an organic layer of a monolayer structure including a biphenylenediamine compound represented by the following formula 1 between a first electrode and a light-emitting layer. The organic layer has both hole transport and hole injection properties. Therefore, the organic EL device of the present invention is excellent in lifetime and emission efficiency characteristics even without a separate hole injection layer. The organic layer has a thickness of 50 to 2,000 Å. If the thickness of the organic layer is less than 50 Å, hole transport property may deteriorate. On the other hand, if it exceeds 2,000 Å, a driving voltage may increase:

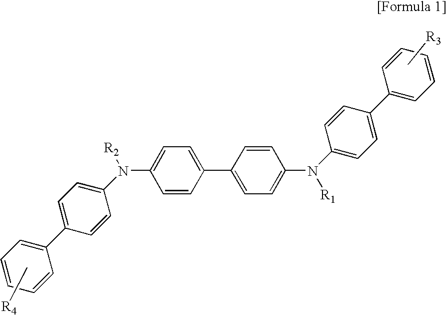

wherein R₁ and R₂ are each independently a substituted or unsubstituted alkyl group of C1-C20 or a substituted or unsubstituted aryl group of C6-C20, R₃ and R₄ are each independently selected from the group consisting of a substituted or unsubstituted alkyl group of C1-C20, a substituted or unsubstituted aryl group of C6-C20, a halogen atom, a nitro group, a cyano group, and a substituted or unsubstituted alkoxy group of C1-C20.

Examples of the compound of the formula 1 include compounds represented by the following formulae 2 through 4:

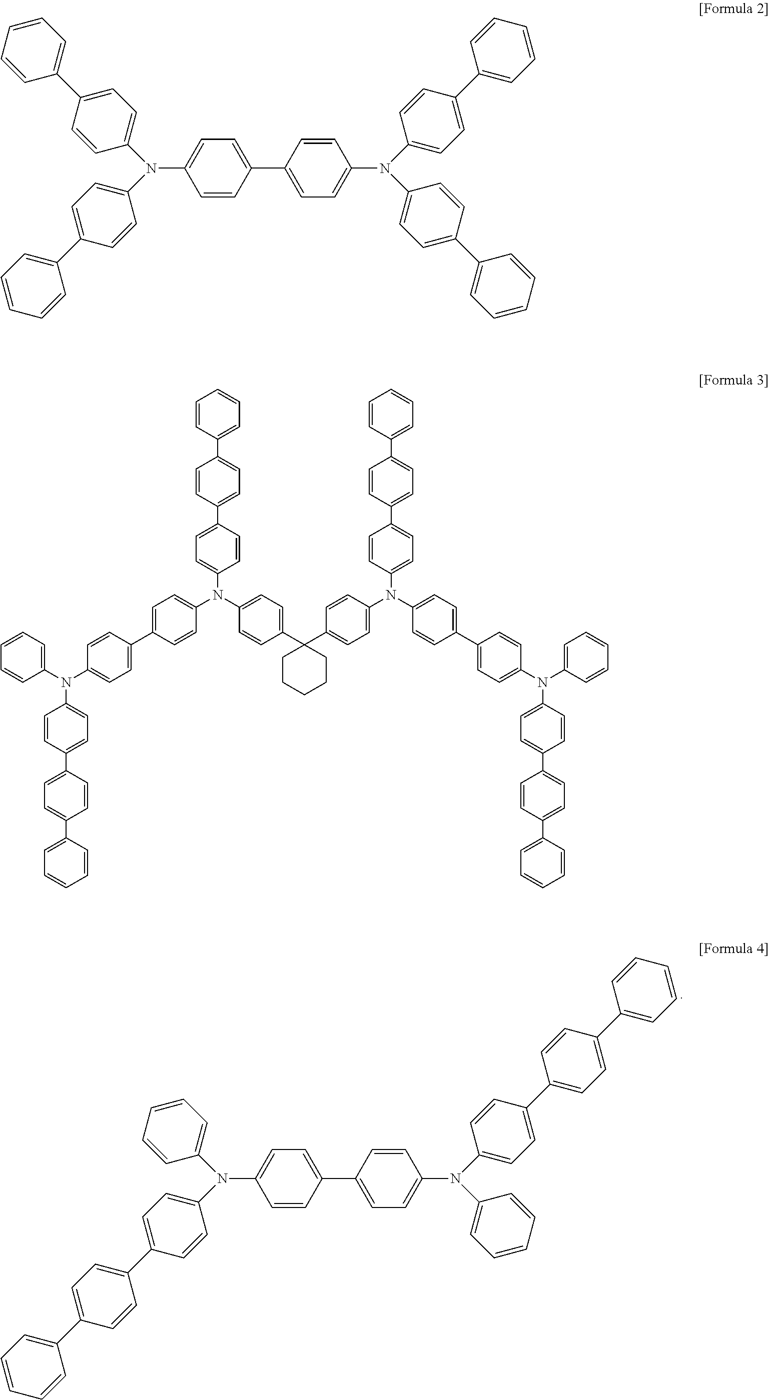

The organic EL device of the present invention may further include a buffer layer including an organic compound with p-type semiconductive property between the first electrode and the organic layer. The buffer layer is formed preferably to a thickness of 1 to 100 Å, in particular 5 Å.

The organic compound with p-type semiconductive property may be a compound represented by the following formula 5:

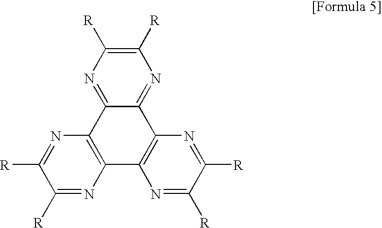

wherein each R is independently a hydrogen atom, an alkyl group of C1-C20, an aryl group of C6-C20, a heteroaryl group of C2-C20, a halogen atom, an alkoxy group of C1-C20, an arylamine group of C6-C20, a nitro group, a cyano group, a nitrile group, —CONR′, or —CO₂R′ where R′ is an alkyl group of C1-C12 or an aryl group of C6-C12.

In the formula 5, it is preferred that R is a cyano group, a nitro group, —CONR′, or —CO₂R′.

The organic compound with p-type semiconductive property serves to facilitate hole injection from an anode used as the first electrode and transport an injected hole to the light-emitting layer. Therefore, the organic EL device of the present invention can have a lower driving voltage and a remarkably enhanced lifetime. The organic compound with p-type semiconductive property also has the capability of forming a stabilized interface with metal oxide which is a material for the first electrode.

Hereinafter, a method of manufacturing an organic EL device of the present invention will be described.

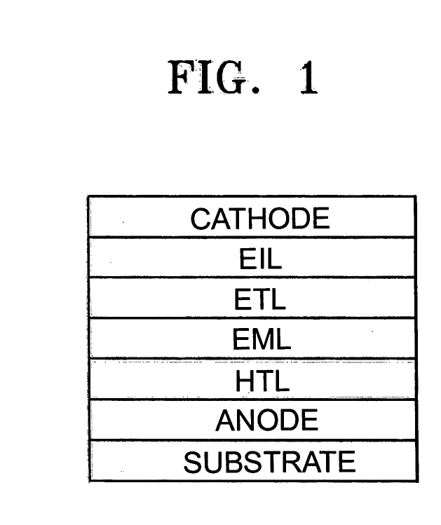

A method of manufacturing an organic EL device according to an embodiment of the present invention will now be described with reference to FIG. 1.

First, an anode material is coated on a substrate to form an anode used as a first electrode. The substrate may be a substrate commonly used for organic EL devices. Preferably, the substrate is a glass substrate or a transparent plastic substrate which is excellent in transparency, surface smoothness, handling property, and water resistance. The anode material may be a material which is excellent in transparency and conductivity, for example, indium tin oxide (ITO), indium zinc oxide (IZO), tin oxide (SnO₂), or zinc oxide (ZnO).

A hole transport layer (HTL) is formed on the anode by depositing a compound of the formula 1 on the anode.

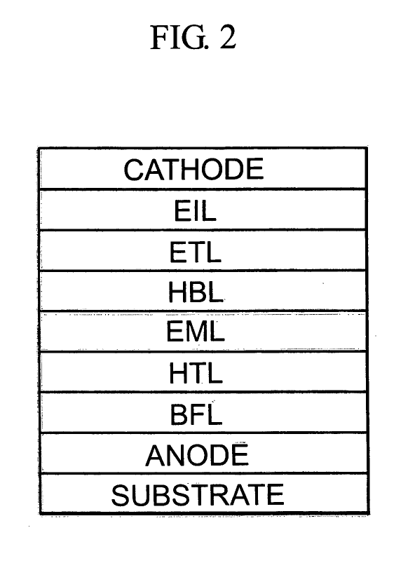

A buffer layer (BFL) may be optionally formed between the anode and the hole transport layer by using an organic compound with p-type semiconductive property as shown in FIG. 2. At this time, there are no particular limitations on film forming methods, but vacuum thermal deposition may be used.

A light-emitting layer (EML) is formed on the hole transport layer using a common emission material. The emission material may be bisthienylpyridine acetylacetonate iridium, bis(benzothienylpyridine)acetylacetonate iridium, bis(2-phenylbenzothiazole)acetylacetonate iridium, bis(1-phenylisoquinoline) Iridium acetylacetonate, tris(1-phenylisoquinoline) Iridium, or the like.

The light-emitting layer may further include a common host, in addition to the above-described material. Examples of the host include CBP (4,4′-N,N′-dicarbazole-biphenyl), Balq (bis(2-methyl-8-hydroxyquinoline) biphenyloxy aluminum), and carbazole compound.

There are no particular limitations on methods of forming the light-emitting layer but vacuum deposition, inkjet printing, laser printing, photolithography, or the like may be used.

Preferably, the light-emitting layer has a thickness of 100 to 800 Å. If the thickness of the light-emitting layer is less than 100 Å, emission efficiency and lifetime may be lowered. On the other hand, if it exceeds 800 Å, a driving voltage may increase.

Preferably, the host is contained in the light-emitting layer in an amount of 80 to 99 parts by weight, based on the total weight (100 parts by weight) of a light-emitting layer forming material (i.e., the total weight of the host and a dopant). If the content of the host is less than 80 parts by weight, triplet extinction may occur, thereby lowering emission efficiency. On the other hand, if it exceeds 99 parts by weight, an emission material may be insufficient, thereby lowering emission efficiency and lifetime.

A hole blocking layer (HBL) is optionally formed on the light-emitting layer by vacuum deposition or spin coating of a hole blocking material as shown in FIG. 2. There are no particular limitations on the hole blocking material provided that it has an electron transport capability and a higher ionization potential than the light-emitting compound. Representative examples of the hole blocking material include Balq, BCP, and TPBI (2,2′,2″-(1,3,5-benzenetrile)tris-[1-phenyl-1H-benzimidazole] as represented by the following structural formulae. Preferably, the hole blocking layer has a thickness of 30 to 500 Å. If the thickness of the hole blocking layer is less than 30 Å, hole blocking characteristics may become worsen, thereby lowering emission efficiency. On the other hand, if it exceeds 500 Å, a driving voltage may increase.

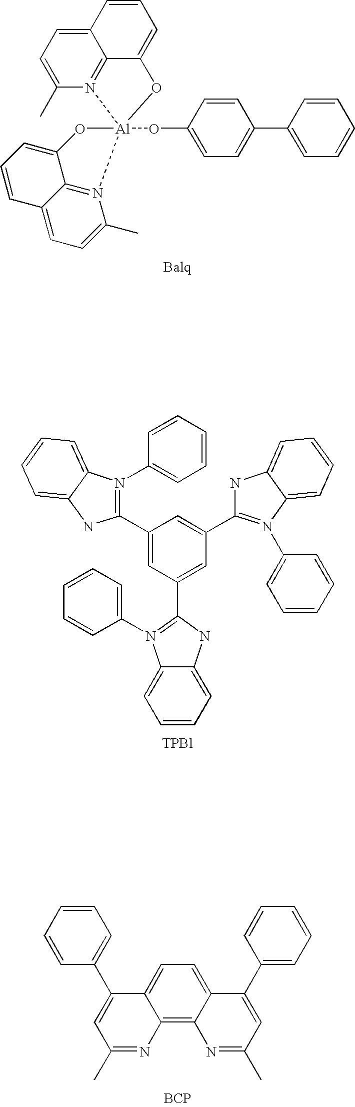

An electron transport layer (ETL) is formed on the hole blocking layer by vacuum deposition or spin coating of an electron transport layer material. There are no particular limitations on the electron transport layer material but Alq3 (tris(8-Hydroxyquinoline) Aluminum) may be used. Preferably, the electron transport layer has a thickness of 50 to 600 Å. If the thickness of the electron transport layer is less than 50 Å, lifetime characteristics may be lowered. On the other hand, if it exceeds 600 Å, a driving voltage may be lowered.

An electron injection layer (EIL) may be optionally formed on the electron transport layer. An electron injection layer material may be LiF, NaCl, CsF, Li₂O, BaO, Liq (represented by the following structural formula), etc:

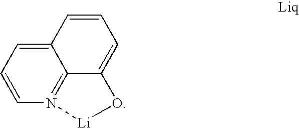

Preferably, the electron injection layer has a thickness of 1 to 100 Å. If the thickness of the electron injection layer is less than 1 Å, electron injection property may be poor, thereby increasing a driving voltage. On the other hand, if it exceeds 100 Å, the electron injection layer may serve as an insulating layer, thereby increasing a driving voltage.

Finally, a cathode used as a second electrode is formed on the electron injection layer by vacuum thermal deposition of a cathode metal to complete an organic EL device.

The cathode metal may be lithium (Li), magnesium (Mg), aluminum (Al), aluminum-lithium (Al—Li), calcium (Ca), magnesium-indium (Mg—In), magnesium-silver (Mg—Ag), or the like.

The organic EL device of the present invention may include, as needed, one or two interlayers among the anode, the hole injection layer, the hole transport layer, the light-emitting layer, the electron transport layer, the electron injection layer, and the anode.

In the formulae as used in the present invention, examples of the unsubstituted alkyl group of C1-C20 include methyl, ethyl, propyl, isobutyl, sec-butyl, pentyl, iso-amyl, and hexyl. One or more hydrogen atoms on the alkyl group may be substituted by halogen atom, halide, a hydroxy group, a nitro group, a cyano group, an amino group, an amidino group, hydrazine, hydrazone, a carboxyl group, a sulfonic acid group, a phosphoric acid group, a lower alkyl group of C1-C15, or a lower alkoxy group of C1-C15.

The aryl group, which is used alone or in combination, refers to an aromatic system of 6-30 carbon atoms containing one or more rings. The rings may be attached to each other as a pendant group or may be fused. Examples of the aryl include phenyl, naphthyl, tetrahydronaphthyl, indane, and biphenyl. One or more hydrogen atoms on the aryl group may be substituted by the same substituents as those mentioned in the above definition of the alkyl group of C1-C15 or a substituent represented by the following formula:

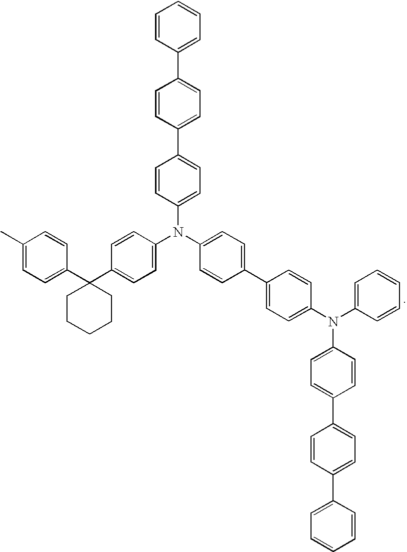

Hereinafter, the present invention will be described more specifically by Examples. However, the following Examples are provided only for illustrations and thus the present invention is not limited to or by them.

### Example 1

A 15 Ω/cm² (1,200 Å) ITO glass substrate (manufactured by Corning Inc.) was cut into pieces of 50 mm×50 mm×0.7 mm in size, followed by ultrasonic cleaning in isopropyl alcohol and deionized water (5 minutes for each) and then UV/ozone cleaning (30 minutes), to be used as an anode.

A hole transport layer was formed to a thickness of 100 Å on the substrate by vacuum deposition of a compound of the formula 3.

A light-emitting layer was formed to a thickness of about 400 Å on the hole transport layer by co-deposition of CBP and Irppy₃[tris(phenylpyridine)iridium].

An electron transport layer was formed to a thickness of about 300 Å on the light-emitting layer by deposition of Alq3 used as an electron transport material.

A LiF/AI electrode was formed by sequential vacuum deposition of LiF (10 Å, electron injection layer) and Al (1,000 Å, cathode) to complete an organic EL device.

### Example 2

An organic EL device was manufactured in the same manner as in Example 1 except that a buffer layer was formed by vacuum thermal deposition of a compound (R═CN) of the formula 5 prior to forming the hole transport layer.

### Comparative Example 1

A 15 Ω/cm² (1,200 Å) ITO glass substrate (manufactured by Corning Inc.) was cut into pieces of 50 mm×50 mm×0.7 mm in size, followed by ultrasonic cleaning in isopropyl alcohol and deionized water (5 minutes for each) and then UV/ozone cleaning (30 minutes), to be used as an anode.

A hole injection layer was formed to a thickness of about 200 Å on the substrate by deposition of TCTA represented by the following formula:

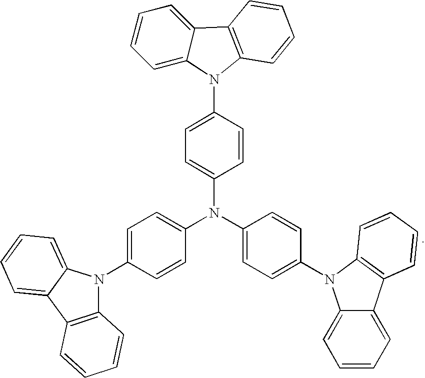

A hole transport layer was formed to a thickness of 600 Å on the hole injection layer by vacuum deposition of N,N′-di(1-naphtyl)-N,N′-diphenylbenzidine (NPD).

A light-emitting layer was formed to a thickness of about 400 Å on the hole transport layer by co-deposition of CBP and Irppy3.

An electron transport layer was formed to a thickness of about 300 Å on the light-emitting layer by deposition of Alq3 used as an electron transport material.

An LiF/AI electrode was formed on the electron transport layer by sequential vacuum deposition of LiF (10 Å, electron injection layer) and Al (1,000 Å, cathode) to complete an organic EL device.

Lifetime characteristics for the organic EL devices manufactured in Examples 1-2 and Comparative Example 1 were evaluated.

As a result, the organic EL devices of Examples 1 and 2 exhibited enhanced lifetime characteristics of 600 and 700 hours, respectively, at 5,000 cd/m², as compared to the lifetime characteristics (about 500 hours at 5,000 cd/m²) of the organic EL device of Comparative Example 1.

According to an organic EL device of the present invention, an organic layer is formed between a first electrode and a light-emitting layer using a 4,4′-biphenylenediamine compound of the formula 1 and has both hole transport and hole injection properties. Therefore, the organic EL device of the present invention has improved lifetime characteristics in spite of absence of a hole injection layer. A buffer layer including an organic compound with p-type semiconductive property may be further formed between the first electrode and the organic layer including the 4,4′-biphenylenediamine compound of the formula 1 to facilitate hole injection from the first electrode and transport an injected hole to the light-emitting layer. Therefore, the organic EL device of the present invention can have a lower driving voltage, thereby improving a device lifetime.

1-15. (canceled)

16. An organic EL device, comprising:
a first electrode;
a second electrode;
a light-emitting layer formed between said first electrode and said second electrode;
an organic layer interposed between the first electrode and the light-emitting layer, the organic layer having a thickness of 50 to 2,000 Å, said organic layer having a monolayer structure and comprising a compound represented by the formula 3: 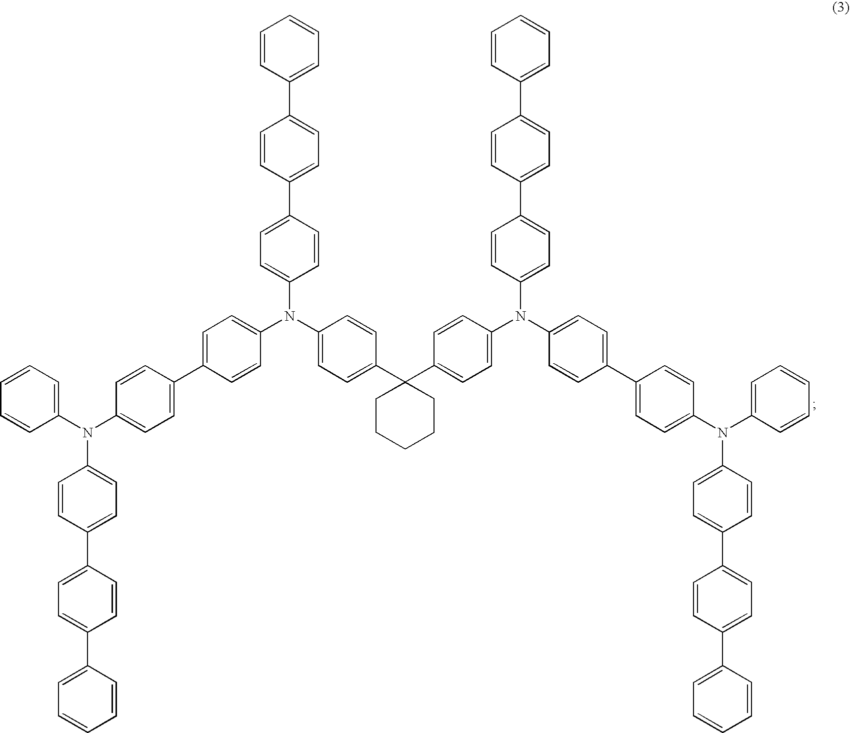
and
a buffer layer comprising an organic compound with p-type semiconductive property between the first electrode and the organic layer, the buffer layer having a thickness of 1 to 100 Å, the organic compound with p-type semiconductive property represented by the formula 5: 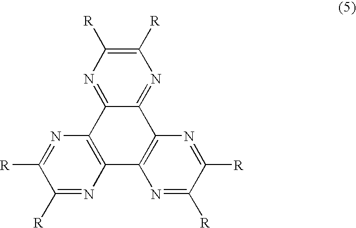
wherein each R is independently selected from the group consisting of a hydrogen atom, an alkyl group of C1-C20, an aryl group of C6-C20, a heteroaryl group of C2-C20, a halogen atom, an alkoxy group of C1-C20, an arylamine group of C6-C20, a nitro group, a cyano group, a nitrile group, —CONR′, and —CO₂R′ where R′ is an alkyl group of C1-C12 or an aryl group of C6-C12.

17-18. (canceled)

19. The organic EL device of claim 16, wherein the light-emitting layer is made of at least one selected from the group consisting of bisthienylpyridine acetylacetonate iridium, bis(benzothienylpyridine)acetylacetonate iridium, bis(2-phenylbenzothiazole)acetylacetonate iridium, bis(1-phenylisoquinoline) Iridium acetylacetonate, and tris(1-phenylisoquinoline) Iridium.

20. The organic EL device of claim 16, wherein the light-emitting layer has a thickness of 100 to 800 Å.

21. (canceled)

22. The organic EL device of claim 16, wherein the buffer layer has a thickness of 5 Å.

23. The organic EL device of claim 16, wherein the organic layer has a thickness of 2,000 Å, and the buffer layer has a thickness of 5 Å.

24. The organic EL device of claim 16, wherein the organic layer has a thickness of 2,000 Å.
